(19) United States
(12) Patent Application Publication
(10) Pub. No.: US 2024/0203964 A1
(43) Pub. Date: Jun. 20, 2024

(54) SEMICONDUCTOR PACKAGE

(71) Applicant: SAMSUNG ELECTRONICS CO., LTD., Suwon-si (KR)

(72) Inventor: Ara LEE, Suwon-si (KR)

(21) Appl. No.: 18/502,702

(22) Filed: Nov. 6, 2023

(30) Foreign Application Priority Data
Dec. 14, 2022 (KR) 10-2022-0174707

(51) Int. Cl. H01L 25/16; H01L 23/00; H01L 23/498; H01L 23/522; H10B 80/00

(52) U.S. Cl. CPC H01L 25/162; H01L 23/49822; H01L 23/5223; H01L 24/08; H01L 24/48; H10B 80/00; H01L 2224/08225; H01L 2224/48227; H01L 2924/1432; H01L 2924/1433; H01L 2924/1438; H01L 2924/19041; H01L 2924/19105

(57) ABSTRACT

A semiconductor package includes a lower substrate, a lower device on a center of the lower substrate, an upper substrate on the lower device and the lower substrate, and a plurality of post electrodes between a region adjacent an edge of the lower substrate and a region adjacent an edge of the upper substrate. The plurality of post electrodes connect the lower substrate to the upper substrate. A plurality of passive devices are between the plurality of post electrodes and the region adjacent the edge of the lower substrate and connect the plurality of post electrodes to the lower substrate.

### CROSS-REFERENCE TO RELATED APPLICATION

This U.S. nonprovisional application claims priority under 35 U.S.C. § 119 to Korean Patent Application No. 10-2022-0174707 filed on Dec. 14, 2022 in the Korean Intellectual Property Office, the disclosure of which is hereby incorporated by reference in its entirety.

### BACKGROUND

The present inventive concepts relate to packages, and more particularly, to semiconductor packages.

The sizes of semiconductor chips are becoming smaller with high integration of semiconductor chips. In addition, with the reduction in size of semiconductor chips, it may become hard to handle and test these smaller semiconductor chips. A package on which application processors are mounted may include a capacitor to improve electrical properties. However, because the packages are smaller, it may be difficult to mount the capacitor thereon.

### SUMMARY

Some embodiments of the present inventive concepts provide semiconductor packages capable of suppressing an increase in package height and reducing power noise.

According to some embodiments of the present inventive concepts, a semiconductor package may comprise: a lower substrate; a lower device on a center of the lower substrate; an upper substrate on the lower device and the lower substrate; a plurality of post electrodes between a region adjacent an edge of the lower substrate and a region adjacent an edge of the upper substrate, wherein the plurality of post electrodes connect the lower substrate to the upper substrate; and a plurality of passive devices between the plurality of post electrodes and the region adjacent the edge of the lower substrate, wherein the plurality of passive devices connect the plurality of post electrodes to the lower substrate.

According to some embodiments of the present inventive concepts, a semiconductor package may comprise: a lower substrate; a lower device on a center of the lower substrate; an upper substrate on the lower device and the lower substrate; a plurality of post electrodes between a region adjacent an edge of the lower substrate and a region adjacent an edge of the upper substrate, wherein the plurality of post electrodes connect the lower substrate to the upper substrate; a plurality of passive devices between the plurality of post electrodes and the region adjacent the edge of the lower substrate, wherein the plurality of passive devices connect the plurality of post electrodes to the lower substrate. The plurality of post electrodes may include: a plurality of first post electrodes between the lower substrate and the upper substrate; and a plurality of second post electrodes between the plurality of passive devices and the upper substrate, wherein the plurality of second post electrodes are shorter than the plurality of first post electrodes.

According to some embodiments of the present inventive concepts, a semiconductor package may comprise: a lower substrate; a lower device on a center of the lower substrate; a first upper substrate on the lower device and the lower substrate; a second upper substrate on the first upper substrate; a plurality of upper devices on the second upper substrate; a plurality of post electrodes between a region adjacent an edge of the lower substrate and a region adjacent an edge of the first upper substrate, wherein the plurality of post electrodes connect the lower substrate to the first upper substrate; and a plurality of passive devices between the plurality of post electrodes and the region adjacent the edge of the lower substrate, wherein the plurality of passive devices connect the plurality of post electrodes to the lower substrate.

### BRIEF DESCRIPTION OF THE DRAWINGS

FIG. 1 illustrates a cross-sectional view showing an example of a semiconductor package according to some embodiments of the present inventive concepts.

FIG. 2 illustrates a plan view showing an example of a lower substrate, a lower device, passive devices, and post electrodes of FIG. 1.

FIG. 3 illustrates a cross-sectional view showing an example of a semiconductor package according to some embodiments of the present inventive concepts.

FIG. 4 illustrates a plan view showing an example of a lower substrate, a lower device, passive devices, and post electrodes of FIG. 3.

FIG. 5 illustrates a cross-sectional view showing an example of a semiconductor package according to some embodiments of the present inventive concepts.

FIG. 6 illustrates a plan view showing an example of passive devices in a semiconductor package according to some embodiments of the present inventive concepts.

### DETAILED DESCRIPTION

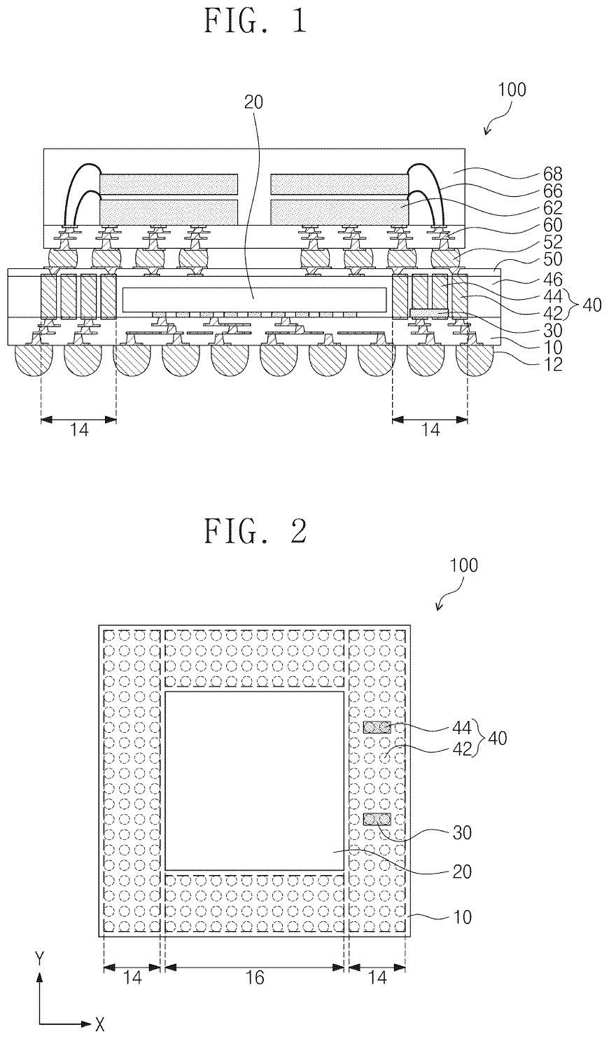

FIG. 1 shows an example of a semiconductor package according to some embodiments of the present inventive concepts. FIG. 2 shows an example of a lower substrate, a lower device, passive devices, and post electrodes of FIG. 1.

Referring to FIGS. 1 and 2, a semiconductor package 100 of the present inventive concepts may include a fan-out wafer level package (FOWLP). According to an embodiment, the semiconductor package 100 of the present inventive concepts may include a lower substrate 10, a lower device 20, passive devices 30, post electrodes 40, a first upper substrate 50, a second upper substrate 60, and upper devices 62.

The lower substrate 10 may be provided below the lower device 20 and the passive devices 30. For example, the lower substrate 10 may include a redistribution substrate. For another example, the lower substrate 10 may include a printed circuit board, but the present inventive concepts are not limited thereto. The lower substrate 10 may have lower solder balls 12. The lower solder balls 12 may be provided on a lower portion of the lower substrate 10.

According to an embodiment, the lower substrate 10 may have power regions 14 and communication regions 16. The power regions 14 and the communication regions 16 may be provided outside the lower device 20.

The power regions 14 may be provided on regions of the lower substrate adjacent opposite edges of the lower substrate 10 that face each other in a first direction X, as illustrated in FIG. 2. The power regions 14 may be sections to which are connected the post electrodes 40 for power and ground.

The communication regions 16 may be provided on regions of the lower substrate adjacent opposite edges of the lower substrate 10 that face each other in a second direction Y, as illustrated in FIG. 2. The communication regions 16 may be sections to which are connected the post electrodes 40 for communication of the lower device 20 and the upper devices 62.

The lower device 20 may be mounted on a center of the lower substrate 10. The lower device 20 may be provided between the power regions 14 that face each other in the first direction X. In addition, the lower device 20 may be provided between the communication regions 16 that face each other in the second direction Y. The lower device 20 may be connected to the upper devices 62 through the lower substrate 10, the post electrodes 40, the first upper substrate 50, and the second upper substrate 60. The lower device 20 may include a data processing device. For example, the lower device 20 may include an application processor (AP).

The lower substrate 10 may be provided with the passive devices 30 on a region of the lower substrate adjacent an edge and beyond the lower device 20, as illustrated in FIG. 2. The passive devices 30 may be provided between the post electrodes 40 and the power regions 14 of the lower substrate 10. For example, each of the passive devices 30 may include a capacitor. The passive devices 30 may remove power noise or ground noise provided between the power regions 14 and the post electrodes 40. The passive devices 30 may decrease lengths of the post electrodes 40 to be mounted between the lower substrate 10 and the first upper substrate 50 without an increase in height or size of the semiconductor package 100.

The lower substrate 10 may be provided with the post electrodes 40 on the region adjacent an edge and beyond the lower device 20, as illustrated in FIG. 2. The first upper substrate 50, the second upper substrate 60, and the upper device 62 may be connected through the post electrodes 40 to the lower substrate 10. The post electrodes 40 may be provided on the power regions 14 and the communication regions 16 adjacent an edge of the lower substrate 10. The post electrodes 40 on the power regions 14 may be electrodes for power lines and ground lines. The post electrodes 40 of the power lines, the passive devices 30, and the lower substrate 10 may be connected in series to decrease inductance. The post electrodes 40 of the ground lines may be provided adjacent to the passive devices 30 to electrically shield the passive devices 30. The post electrodes 40 on the communication regions 16 may be signal lines or data lines, but the present inventive concepts are not limited thereto. The post electrodes 40 may include copper (Cu). According to an embodiment, the post electrodes 40 may include first post electrodes 42 and second post electrodes 44.

The first post electrodes 42 may be provided between the lower substrate 10 and the first upper substrate 50. The first post electrodes 42 may directly connect the first upper substrate 50 to the lower substrate 10.

The second post electrodes 44 may be provided between the passive devices 30 and the first upper substrate 50. The second post electrodes 44 may connect the first upper substrate 50 to the passive devices 30. When viewed in vertical section (FIG. 1), the second post electrodes 44 may be shorter than the first post electrodes 42. The second post electrodes 44 may have their bottom surfaces higher than those of the first post electrodes 42.

A first underfill layer 46 may be provided between the post electrodes 40. The first underfill layer 46 may be provided between the passive devices 30 and the post electrodes 40. The first underfill layer 46 may be provided on the lower device 20. The first underfill layer 46 may have a top surface coplanar with those of the post electrodes 40. For example, the first underfill layer 46 may include epoxy. Alternatively, the first underfill layer 46 may include a polymer compound, alumina (Al₂O₃), aluminum nitride (AlN), or silicon carbide (SiC), but the present inventive concepts are not limited thereto.

The first upper substrate 50 may be provided on the first underfill layer 46 and the post electrodes 40. The first upper substrate 50 may be connected to the post electrodes 40. For example, the first upper substrate 50 may include a redistribution substrate. For another example, the first upper substrate 50 may include an interposer substrate or a printed circuit board, but the present inventive concepts are not limited thereto.

The second upper substrate 60 may be provided on the first upper substrate 50. The second upper substrate 60 may be connected through upper solder balls 52 to the first upper substrate 50. The upper solder balls 52 may be provided between the first upper substrate 50 and the second upper substrate 60. For example, the second upper substrate 60 may include a redistribution substrate. Although not shown, the second upper substrate 60 may include a printed circuit board, but the present inventive concepts are not limited thereto. A second underfill layer may be provided between the first upper substrate 50 and the second upper substrate 60. The second underfill layer may include epoxy, alumina (Al₂O₃), aluminum nitride (AlN), or silicon carbide (SIC).

The upper devices 62 may be provided on the second upper substrate 60. The upper devices 62 may be stacked (i.e., the upper devices 62 are on top of each other). The upper devices 62 may be connected through wires 66 to the second upper substrate 60 and the lower device 20. The upper devices 62 may be connected to the second upper substrate 60 via a through silicon via (TSV), but the present inventive concepts are not limited thereto. A mold layer 68 may protect the upper devices 62 from the external. The mold layer 68 may include an epoxy molding compound (EMC). According to an embodiment, the upper devices 62 may include a memory device. For example, the upper devices 62 may include a volatile memory device, such as dynamic random access memory (DRAM). For another example, the upper devices 62 may include a nonvolatile memory device, such as flash memory, but the present inventive concepts are not limited thereto.

The semiconductor package 100 of the present inventive concepts may use the passive devices 30 through which the lower substrate 10 is connected to the post electrodes 40 outside the lower device 20, and thus an increase in package height may be suppressed and power noise may be reduced.

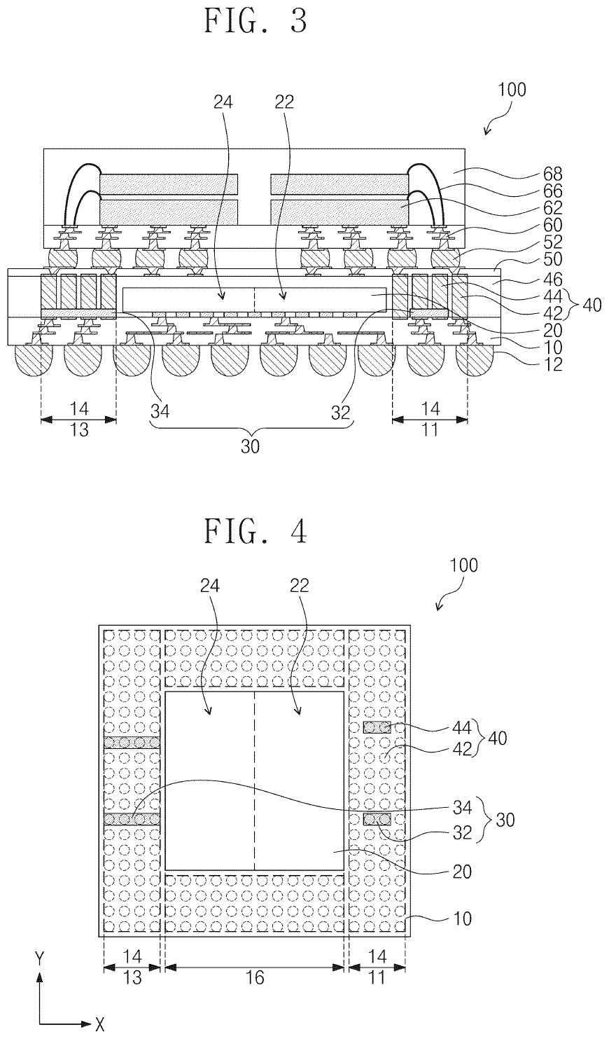

FIG. 3 shows an example of a semiconductor package according to some embodiments of the present inventive concepts. FIG. 4 shows an example of a lower substrate, a lower device, passive devices, and post electrodes of FIG. 3.

Referring to FIGS. 3 and 4, the passive devices 30 may include a first passive device 32 and a second passive device 34. The first passive device 32 may be provided adjacent to one side of the lower device 20. The second passive device 34 may be provided adjacent to another side of the lower device 20. When viewed in plan (FIG. 4), the second passive device 34 may be wider than the first passive device 32. For example, a planar area of the second passive device 34 may be greater than that of the first passive device 32.

The power regions 14 of the lower substrate 10 may include a low-power region 11 and a high-power region 13. The low-power region 11 may be provided on a region adjacent one side edge in the first direction X of the lower substrate 10. The first passive device 32 may be provided on the lower substrate 10 of the low-power region 11, as illustrated in FIG. 4. The high-power region 13 may be provided on a region adjacent another side edge of the lower substrate 10, as illustrated in FIG. 4. The second passive device 34 may be provided on the lower substrate 10 of the high-power region 13.

When viewed in plan (FIG. 4), the lower device 20 may include a first region 22 and a second region 24. The first region 22 may be provided adjacent to the low-power region 11. The first region 22 may be adjacent to the first passive device 32. For example, the first region 22 may include a multi-chip package (MCP) region. The second region 24 may be provided between the first region 22 and the high-power region 13. The second region 24 may be adjacent to the second passive device 34. The second region 24 may include a universal flash storage (UFS) region.

The post electrodes 40, the first upper substrate 50, the second upper substrate 60, and the upper device 62 may be configured identically to those of FIG. 1.

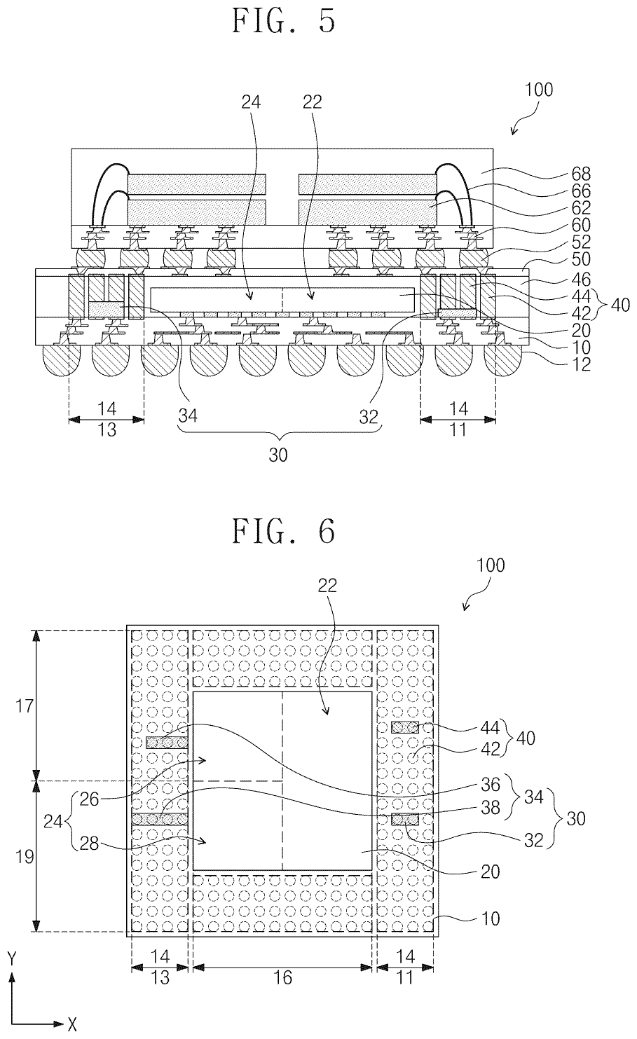

FIG. 5 shows an example of a semiconductor package according to some embodiments of the present inventive concepts.

Referring to FIG. 5, when viewed in vertical section, the second passive device 34 may be thicker than the first passive device 32. For example, the second passive device 34 may have a thickness greater than that of the first passive device 32 in the Y direction. The first passive device 32 may include a single capacitor. The second passive device 34 may include a plurality of stacked capacitors.

The lower substrate 10, the lower device 20, the post electrodes 40, the first upper substrate 50, the second upper substrate 60, and the upper device 62 may be configured identically to those of FIG. 1.

FIG. 6 shows an example of passive devices in a semiconductor package according to some embodiments of the present inventive concepts.

Referring to FIG. 6, the second passive devices 34 may include a third passive device 36 and a fourth passive device 38. The third passive device 36 and the fourth passive device 38 may be provided on the lower substrate 10 of the high-power region 13. When viewed in plan, the third passive device 36 may be wider than the first passive device 32. When viewed in plan, the fourth passive device 38 may be wider than the third passive device 36.

The high-power region 13 of the lower substrate 10 may include a first high-power region 17 and a second high-power region 19. The first high-power region 17 may be provided on a region adjacent one side edge in the second direction Y of the lower substrate 10. The third passive device 36 may be provided on the lower substrate 10 of the first high-power region 17. The second high-power region 19 may be provided on a region adjacent another side edge in the second direction Y of the lower substrate 10. The fourth passive device 38 may be provided on the second high-power region 19.

The second region 24 of the lower device 20 may include a third region 26 and a fourth region 28. The third region 26 may be provided adjacent to the first high-power region 17 and the third passive device 36. The third region 26 may include a universal flash storage (UFS) region. The fourth region 28 may be provided adjacent to the second high-power region 19 and the fourth passive device 38. The fourth region 28 may include a central processing unit (CPU) region or a graphic processing unit (GPU) region.

The post electrodes 40 and the low-power region 11 of the power region 14 may be configured identically to those of FIG. 4.

As discussed above, a semiconductor package according to some embodiments of the present inventive concepts may use a passive device, such as capacitor, through which a lower substrate is connected to post electrodes outside a lower device, and thus an increase in package height may be suppressed and power noise may be reduced.

The above descriptions are specific examples for practicing the present inventive concepts. The present inventive concepts will include not only the embodiments described above but also embodiments that can be easily or simply changed in design. In addition, the present inventive concepts will also include technique that can be easily modified and implemented using the embodiments described above.

What is claimed is:

1. A semiconductor package, comprising:
a lower substrate;
a lower device on a center of the lower substrate;
an upper substrate on the lower device and the lower substrate;
a plurality of post electrodes between a region adjacent an edge of the lower substrate and a region adjacent an edge of the upper substrate, wherein the plurality of post electrodes connect the lower substrate to the upper substrate; and
a plurality of passive devices between the plurality of post electrodes and the region adjacent the edge of the lower substrate, wherein the plurality of passive devices connect the plurality of post electrodes to the lower substrate.

2. The semiconductor package of claim 1, wherein each of the plurality of passive devices comprises a capacitor.

3. The semiconductor package of claim 1, wherein the plurality of passive devices comprise:
a first passive device on a region adjacent one side edge of the lower substrate; and
a second passive device on a region adjacent another side edge of the lower substrate.

4. The semiconductor package of claim 3, wherein the second passive device is wider than the first passive device.

5. The semiconductor package of claim 3, wherein the second passive device is thicker than the first passive device.

6. The semiconductor package of claim 3, wherein the lower substrate comprises:
a low-power region on which the first passive device is mounted;
a high-power region on which the second passive device is mounted; and
a plurality of signal regions between the low-power region and the high-power region.

7. The semiconductor package of claim 6, wherein the high-power region comprises:
a first high-power region; and
a second high-power region adjacent to the first high-power region.

8. The semiconductor package of claim 7, wherein the second passive device comprises:
a third passive device on the first high-power region; and
a fourth passive device on the second high-power region, wherein the fourth passive device is wider than the third passive device.

9. The semiconductor package of claim 8, wherein the lower substrate comprises:
a multi-chip package (MCP) region adjacent to the first passive device;
a universal flash storage (UFS) region adjacent to the third passive device; and
a central processing unit (CPU) region or a graphic processing unit (GPU) adjacent to the fourth passive device.

10. The semiconductor package of claim 1, wherein the lower device comprises an application processor.

11. A semiconductor package, comprising:
a lower substrate;
a lower device on a center of the lower substrate;
an upper substrate on the lower device and the lower substrate;
a plurality of post electrodes between a region adjacent an edge of the lower substrate and a region adjacent an edge of the upper substrate, wherein the plurality of post electrodes connect the lower substrate to the upper substrate; and
a plurality of passive devices between the plurality of post electrodes and the region adjacent the edge of the lower substrate, wherein the plurality of passive devices connect the plurality of post electrodes to the lower substrate,
wherein the plurality of post electrodes comprise:
a plurality of first post electrodes between the lower substrate and the upper substrate; and
a plurality of second post electrodes between the plurality of passive devices and the upper substrate, wherein the plurality of second post electrodes are shorter than the plurality of first post electrodes.

12. The semiconductor package of claim 11, wherein the lower substrate comprises:
a low-power region;
a high-power region parallel to the low-power region; and
a plurality of signal regions between the low-power region and the high-power region.

13. The semiconductor package of claim 12, wherein the plurality of passive devices comprise:
a plurality of first passive device on the lower substrate of the low-power region; and
a plurality of second passive devices on the lower substrate of the high-power region.

14. The semiconductor package of claim 13, wherein the plurality of second passive devices are wider or thicker than the plurality of first passive devices.

15. The semiconductor package of claim 13, wherein the lower substrate comprises:
a multi-chip package (MCP) region adjacent to the plurality of first passive devices; and
a universal flash storage (UFS) region adjacent to the plurality of second passive devices.

16. A semiconductor package, comprising:
a lower substrate;
a lower device on a center of the lower substrate;
a first upper substrate on the lower device and the lower substrate;
a second upper substrate on the first upper substrate;
a plurality of upper devices on the second upper substrate;
a plurality of post electrodes between a region adjacent an edge of the lower substrate and a region adjacent an edge of the first upper substrate, wherein the plurality of post electrodes connect the lower substrate to the first upper substrate; and
a plurality of passive devices between the plurality of post electrodes and the region adjacent the edge of the lower substrate, wherein the plurality of passive devices connect the plurality of post electrodes to the lower substrate.

17. The semiconductor package of claim 16, wherein each of the lower substrate, the first upper substrate, and the second upper substrate comprises a redistribution substrate.

18. The semiconductor package of claim 16, further comprising a plurality of solder balls between the first upper substrate and the second upper substrate.

19. The semiconductor package of claim 18, wherein the plurality of post electrodes comprise:
a plurality of first post electrodes between the lower substrate and the first upper substrate; and
a plurality of second post electrodes between the plurality of passive devices and the first upper substrate, wherein the plurality of second post electrodes are shorter than the plurality of first post electrodes.

20. The semiconductor package of claim 18, wherein
the lower device comprises an application processor, and
the plurality of upper devices comprise a memory device.
